(19) United States
(12) Patent Application Publication
(10) Pub. No.: US 2025/0163610 A1
(43) Pub. Date: May 22, 2025

(54) USES OF SPINEL-TYPE SINGLE CRYSTALS AS FERROELECTRICS AND RELAXOR FERROELECTRICS, ENERGY STORAGE MATERIAL AND RECHARGEABLE ENERGY STORAGE PRODUCT

(71) Applicant: UNIVERSITY OF MACAU, Macau (CN)

(72) Inventors: Haifeng LI, Macau (CN); Si WU, Macau (CN); Kaitong SUN, Macau (CN); Zirui ZHAO, Macau (CN)

(21) Appl. No.: 18/710,633

(22) PCT Filed: Jun. 17, 2022
(86) PCT No.: PCT/CN2022/099478

§ 371 Date: May 16, 2024

(30) Foreign Application Priority Data
Dec. 31, 2021 (CN) 202111664897.4

(51) Int. Cl. C30B 29/22; C30B 13/24; H01G 7/06

(52) U.S. Cl. CPC C30B 29/22; C30B 13/24; H01G 7/06

(57) ABSTRACT

Provided are the uses of spinel-type single crystals as ferroelectrics and relaxor ferroelectrics, which can be applied to energy storage materials, and rechargeable energy storage products. In respect of the use of spinel-type single crystals AB₂O₄ as ferroelectrics, in AB₂O₄, A is Ca, Sr, Ba, Ti, V, Cr, Mn, Fe, Co, Ni, Cu or Zn, and B is a transition metal element or a rare earth element. In respect of the use of spinel-type single crystals AB₂O₄ as relaxor ferroelectrics, in AB₂O₄, A is Sr, and B is Tb. The energy storage material comprises a spinel-type single crystal AB₂O₄. The rechargeable energy storage product comprises a spinel-type single crystal AB₂O₄. The spinel-type single crystals AB₂O₄ do not contain lead and exhibit ferroelectricity at room temperature, and individual spinel-type single crystals also exhibit a relaxation property, thus being capable of serving as novel lead-free relaxor ferroelectrics; the spinel-type single crystals are non-toxic and harmless, thereby being greener and more environmentally friendly.

### CROSS-REFERENCE TO RELATED APPLICATIONS

The present disclosure claims the right of priority for Chinese patent application no. “CN 202111664897.4”, filed with the China National Intellectual Property Administration on Dec. 31, 2021, and entitled “USES OF SPINEL-TYPE SINGLE CRYSTALS AS FERROELECTRICS AND RELAXOR FERROELECTRICS, ENERGY STORAGE MATERIAL AND RECHARGEABLE ENERGY STORAGE PRODUCT”, which is incorporated herein by reference in its entirety.

### TECHNICAL FIELD

The present disclosure relates to the technical field of electrochemical materials, and to the use of spinel-type single crystals as ferroelectrics and relaxor ferroelectrics, energy storage materials and rechargeable energy storage products.

### BACKGROUND

With the rapid development of the world economy and the increasing demand for energy by mankind, the excessive exploitation of non-renewable energy sources and environmental pollution problems are becoming increasingly serious. Since 2018, the National Energy Administration has issued and implemented multiple plans and policies to vigorously develop renewable energy, promote green and low-carbon development, and accelerate ecological civilization construction. Especially with the recent introduction of the concept of “carbon neutrality”, a series of new energy sources such as photovoltaics and wind power have gradually moved towards practicality. Due to the widespread issues of these renewable new energy sources, such as intermittency, randomness, and volatility, it is of great significance to further study and develop advanced energy storage equipment and technologies.

Currently, commonly used energy storage capacitors can be divided into ferroelectric, relaxor ferroelectric, antiferroelectric, linear dielectric, etc., depending on the different dielectric materials. Among numerous dielectrics, relaxor ferroelectrics exhibit both ferroelectricity and relaxation properties and are widely used in fields such as modern electronics, military weapons, medical instruments, and aerospace due to several excellent properties. Compared to ordinary ferroelectrics, relaxor ferroelectrics have a higher dielectric constant, lower residual polarization, and better piezoelectric effect and nonlinear effect. In addition, they also have significant temperature and frequency dependence.

Up to now, the research and application of ferroelectrics, including relaxor ferroelectric materials, have mainly focused on lead-based single crystals or ceramics with a perovskite structure. Due to the toxicity of lead, it poses great harm to the environment and human health. Therefore, it is of great practical significance to seek new lead-free ferroelectric materials.

### SUMMARY OF THE INVENTION

The present disclosure provides the use of a spinel-type single crystal AB₂O₄ as a ferroelectric, wherein in AB₂O₄, A is Ca, Sr, Ba, Ti, V, Cr, Mn, Fe, Co, Ni, Cu or Zn, and B is a transition metal element or a rare earth element.

In an optional embodiment, B is Sc, Y, La, Ce, Pr, Nd, Pm, Sm, Eu, Gd, Tb, Dy, Ho, Er, Tm, Yb or Lu.

In an optional embodiment, B is Al, Mn, Fe, Co, Ni, Sc, Y, La, Ce, Pr, Nd, Pm, Sm, Eu, Gd, Tb, Dy, Ho, Er, Tm, Yb or Lu.

The present disclosure further provides the use of a spinel-type single crystal AB₂O₄ as a relaxor ferroelectric, wherein in AB₂O₄, A is Sr, and B is Tb.

The present disclosure further provides the use of a spinel-type single crystal AB₂O₄ as a relaxor ferroelectric, wherein in AB₂O₄, A is Ca, Sr, Ba, Ti, V, Cr, Mn, Fe, Co, Ni, Cu or Zn, and B is a transition metal element or a rare earth element.

In an optional embodiment, B is Sc, Y, La, Ce, Pr, Nd, Pm, Sm, Eu, Gd, Tb, Dy, Ho, Er, Tm, Yb or Lu.

In an optional embodiment, B is Al, Mn, Fe, Co, Ni, Sc, Y, La, Ce, Pr, Nd, Pm, Sm, Eu, Gd, Tb, Dy, Ho, Er, Tm, Yb or Lu.

In an optional embodiment, the spinel-type single crystal AB₂O₄ is prepared by a method comprising
synthesizing a polycrystal powder of AB₂O₄ according to the chemical composition of the spinel-type single crystal AB₂O₄;
pressing the polycrystal powder of AB₂O₄ into a blank;
and
calcining the blank at 900-1400° C. for 12-48 h, and then allowing the growth of the single crystal by using a laser floating zone method.

In an optional embodiment, the laser floating zone method for growing the single crystal is carried out under an inert gas atmosphere, with the content of oxygen in the inert gas atmosphere being less than or equal to 20%.

In an optional embodiment, the inert gas is argon.

In an optional embodiment, the pressure intensity is controlled at 0-10 MPa when the laser floating zone method is used for growing the single crystal.

In an optional embodiment, the polycrystal powder of AB₂O₄ is pressed into a blank by means of isostatic pressing.

In an optional embodiment, the polycrystal powder of AB₂O₄ is pressed into a blank by means of charging the polycrystal powder of AB₂O₄ into a balloon and pressing and shaping same by means of isostatic pressing.

The present disclosure further discloses an energy storage material comprising a spinel-type single crystal AB₂O₄, where A is Ca, Sr, Ba, Ti, V, Cr, Mn, Fe, Co, Ni, Cu or Zn, and B is a transition metal element or a rare earth element.

In an optional embodiment, B is Sc, Y, La, Ce, Pr, Nd, Pm, Sm, Eu, Gd, Tb, Dy, Ho, Er, Tm, Yb or Lu.

In an optional embodiment, B is Al, Mn, Fe, Co, Ni, Sc, Y, La, Ce, Pr, Nd, Pm, Sm, Eu, Gd, Tb, Dy, Ho, Er, Tm, Yb or Lu.

The present disclosure further discloses a rechargeable energy storage product comprising a spinel-type single crystal AB₂O₄, where A is Ca, Sr, Ba, Ti, V, Cr, Mn, Fe, Co, Ni, Cu or Zn, and B is a transition metal element or a rare earth element.

In an optional embodiment, B is Sc, Y, La, Ce, Pr, Nd, Pm, Sm, Eu, Gd, Tb, Dy, Ho, Er, Tm, Yb or Lu.

In an optional embodiment, B is Al, Mn, Fe, Co, Ni, Sc, Y, La, Ce, Pr, Nd, Pm, Sm, Eu, Gd, Tb, Dy, Ho, Er, Tm, Yb or Lu.

In an optional embodiment, the spinel-type single crystal AB₂O₄ is prepared by a method comprising:
synthesizing a polycrystal powder of AB₂O₄ according to the chemical composition of the spinel-type single crystal AB₂O₄;
pressing the polycrystal powder of AB₂O₄ into a blank;
calcining the blank at 900-1400° C. for 12-48 h, and then allowing the growth of the single crystal by using a laser floating zone method.

In an optional embodiment, the single crystal is grown by using a laser floating zone method in an environment of inert gas atmosphere, with the content of oxygen in the inert gas atmosphere being less than or equal to 20%.

In an optional embodiment, the pressure intensity is controlled at 0-10 MPa when the laser floating zone method is used for growing the single crystal.

### BRIEF DESCRIPTION OF THE DRAWINGS

To illustrate the technical solutions of the present disclosure examples more clearly, the drawings used in the examples will be briefly introduced below. The following drawings only show certain examples of the present disclosure, and therefore should not be considered as limiting the scope. For a person skilled in the art, other related drawings also can be obtained according to the drawings without creative efforts.

FIG. 1 shows a change curve of the dielectric constant ε and dielectric loss tan δ of the spinel-type single crystal provided in example 1 as a function of temperature at 0.1 kHz, 0.2 kHz, 0.5 kHz, and 1 kHz.

FIG. 2 shows the test results of electric field hysteresis loop of the spinel-type single crystal provided in example 1 along the c axis at room temperature.

FIG. 3 shows the test results of electric field hysteresis loop of the spinel-type single crystal provided in example 1 along the a axis at different temperatures (1.8 K, 260 K, 280 K, and 300 K).

FIG. 4 shows the test results of electric field hysteresis loop of the spinel-type single crystal provided in example 1 along the b axis at different temperatures (1.8 K, 260 K, 280 K, and 300 K).

FIG. 5 shows a change curve of the dielectric constant ε and dielectric loss tan δ of the spinel-type single crystal provided in example 2 as a function of temperature at 1 kHz, 10 kHz, and 100 kHz; and

FIG. 6 shows a change curve of the dielectric constant ε and dielectric loss tan δ of the spinel-type single crystal provided in example 3 as a function of temperature at 1 kHz, 10 kHz, and 100 kHz.

### DETAILED DESCRIPTION OF EMBODIMENTS

To make the objects, technical solutions and advantages of embodiments and examples of the present disclosure clearer, the technical solutions in the embodiments and examples of the present disclosure will be clearly and completely described below. If specific conditions are not specified in embodiments and the examples, conventional conditions or conditions recommended by a manufacturer are followed. The reagents or instruments used therein, where no manufacturer is specified, are all commercially available conventional products.

The use of spinel-type single crystals as relaxor ferroelectrics, the energy storage material and the rechargeable energy storage product provided in the examples of the present disclosure will be described below.

An embodiment of the present disclosure provides the use of a spinel-type single crystal AB₂O₄ as a ferroelectric, wherein in AB₂O₄, A is Ca, Sr, Ba, Ti, V, Cr, Mn, Fe, Co, Ni, Cu or Zn, and B is a transition metal element or a rare earth element.

In some embodiments, B is Sc, Y, La, Ce, Pr, Nd, Pm, Sm, Eu, Gd, Tb, Dy, Ho, Er, Tm, Yb or Lu.

In some embodiments, B is Al, Mn, Fe, Co, Ni, Sc, Y, La, Ce, Pr, Nd, Pm, Sm, Eu, Gd, Tb, Dy, Ho, Er, Tm, Yb or Lu.

An embodiment of the present disclosure further provides the use of a spinel-type single crystal AB₂O₄ as a relaxor ferroelectric, wherein in AB₂O₄, A is Ca, Sr, Ba, Ti, V, Cr, Mn, Fe, Co, Ni, Cu or Zn, and B is a transition metal element or a rare earth element.

The inventors have found that the spinel-type single crystals above exhibit ferroelectricity at room temperature and are novel ferroelectrics, which are lead-free and thus are greener, safer and more environmentally friendly, and can be used as a new generation of excellent energy storage materials and fast rechargeable materials.

In some embodiments, for the use of a spinel-type single crystal AB₂O₄ as a relaxor ferroelectric, in AB₂O₄, A is Sr, and B is Tb.

The applicants have found that among the spinel-type single crystals above, SrTb₂O₄ has not only ferroelectricity but also relaxation properties. It is a novel relaxor ferroelectric, which is lead-free and thus is greener, safer and more environmentally friendly, and can be used as a new generation of excellent energy storage materials and fast rechargeable materials, and also has a broad application prospect in fields such as micro-positioners, actuators, and smart structures.

In some embodiments, the B element is Sc, Y, La, Ce, Pr, Nd, Pm, Sm, Eu, Gd, Tb, Dy, Ho, Er, Tm, Yb or Lu.

In some embodiments, B is Al, Mn, Fe, Co, Ni, Sc, Y, La, Ce, Pr, Nd, Pm, Sm, Eu, Gd, Tb, Dy, Ho, Er, Tm, Yb or Lu.

An embodiment of the present disclosure further provides a method for preparing the spinel-type single crystal above, the method comprising:
S1, synthesizing a polycrystal powder of AB₂O₄ according to the chemical composition of the spinel-type single crystal AB₂O₄;
S2, pressing the polycrystal powder of AB₂O₄ into a blank;
S3, calcining the blank at 900-1400° C. for 12-48 h, and then allowing the growth of the single crystal by using a laser floating zone method. It is believed that without being bound by theory, the laser floating zone method is suitable for growing large single crystals with a high melting point and a high quality.

In some embodiments, in step S2, the calcination temperature may be, for example, 900-1200° C., 1200-1400° C., 950-1350° C., 1000-1300° C., or 1100-1200° C., such as 900° C., 1000° C., 1100° C., 1200° C., 1300° C., and 1400° C. The calcination time may be, for example, 12-36 h, 36-48 h, 15-45 h, 10-35 h, or 15-30 h, such as 12 h, 14 h, 16 h, 18 h, 22 h, 24 h, 28 h, 32 h, 34 h, 36 h, 38 h, 40 h, 42 h, 44 h, and 48 h.

In some embodiments, in step S2, the polycrystal powder of AB₂O₄ is charged into a balloon and pressed into a blank of a fixed solid shape by means of isostatic pressing.

In some embodiments, in step S3, the calcination is carried out under an inert atmosphere at a pressure intensity of 0-10 MPa.

In some embodiments, the inert gas is argon.

In some embodiments, the inert gas is argon. The inert atmosphere may contain oxygen, with the content of oxygen being less than or equal to 20%.

An example of the present disclosure provides the use of a spinel-type single crystal AB₂O₄ as a relaxor ferroelectric in an energy storage material.

The energy storage material provided in an example of the present disclosure comprises a spinel-type single crystal AB₂O₄, where A is Ca, Sr or Ba, and B is a transition metal element or a rare earth element.

The fast rechargeable product provided in an example of the present disclosure comprises a spinel-type single crystal AB₂O₄, where A is Ca, Sr or Ba, and B is a transition metal element or a rare earth element.

It has been found through research that the spinel-type single crystals involved in the present disclosure exhibit ferroelectricity at room temperature, and some of the spinel-type single crystals also exhibit a relaxation property and can be used as relaxor ferroelectrics. Such spinel-type single crystals are lead-free and thus are non-toxic, harmless, green and environmentally friendly, which can be used in energy storage materials or rechargeable energy storage products.

### EXAMPLES

The characteristics and performance of the present disclosure will be further described in detail below in combination with the examples.

### Example 1

A polycrystal powder of SrTb₂O₄ was synthesized according to the chemical composition of the spinel-type single crystal SrTb₂O₄.

The polycrystal powder of SrTb₂O₄ was charged into a balloon and pressed into a blank of a fixed solid shape by means of isostatic pressing.

The blank was calcined at 900° C. for 48 h and allowed for growing the single crystal by using a laser floating zone method under a mixed atmosphere of argon and oxygen (with the content of oxygen being 5%), with the pressure intensity being controlled within 0-10 MPa.

### Example 2

A polycrystal powder of SrHo₂O₄ was synthesized according to the chemical composition of the spinel-type single crystal SrHo₂O₄.

The polycrystal powder of SrHo₂O₄ was charged into a balloon and pressed into a blank of a fixed solid shape by means of isostatic pressing.

The blank was calcined at 1400° C. for 12 h and allowed for growing the single crystal by using a laser floating zone method under a mixed atmosphere of argon and oxygen (with the content of oxygen being 3%), with the pressure intensity being controlled within 0-10 MPa.

### Example 3

A polycrystal powder of SrGd₂O₄ was synthesized according to the chemical composition of the spinel-type single crystal SrGd₂O₄.

The polycrystal powder of SrGd₂O₄ was charged into a balloon and pressed into a blank of a fixed solid shape by means of isostatic pressing.

The blank was calcined at 1200° C. for 36 h and allowed for growing the single crystal by using a laser floating zone method under a mixed atmosphere of argon and oxygen (with the content of oxygen being 3%), with the pressure intensity being controlled within 0-10 MPa.

### Experimental Example 1

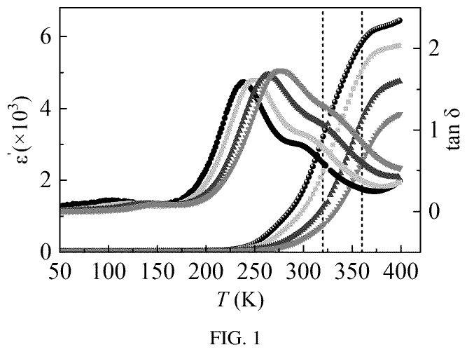

The dielectric constant E and dielectric loss tan δ of the spinel-type single crystal in example 1 at different frequencies were tested as a function of temperature, with the change curve as shown in FIG. 1.

As can be seen from FIG. 1, the dielectric constant has a wide extremum range corresponding to a relatively wide temperature range, which is frequency-dependent, unlike traditional ferroelectrics that exhibit a sharp curie point. The dielectric temperature spectrum and the losses exhibit significant dispersion characteristics with the change in frequency. It exhibits dielectric relaxation characteristics over a wide temperature range. In addition, the dielectric test of the single crystal also shows a significant anisotropy. When the temperature reaches 400 K, the dielectric constant continues to increase with the change in temperature. That is, the single crystal exhibits relaxor-ferroelectricity at a temperature of 400 K or lower. A large dielectric constant is also one of the characteristics of relaxor ferroelectrics.

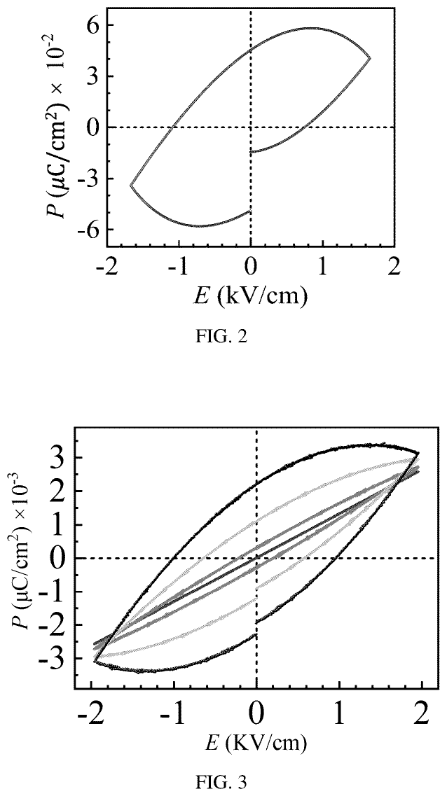

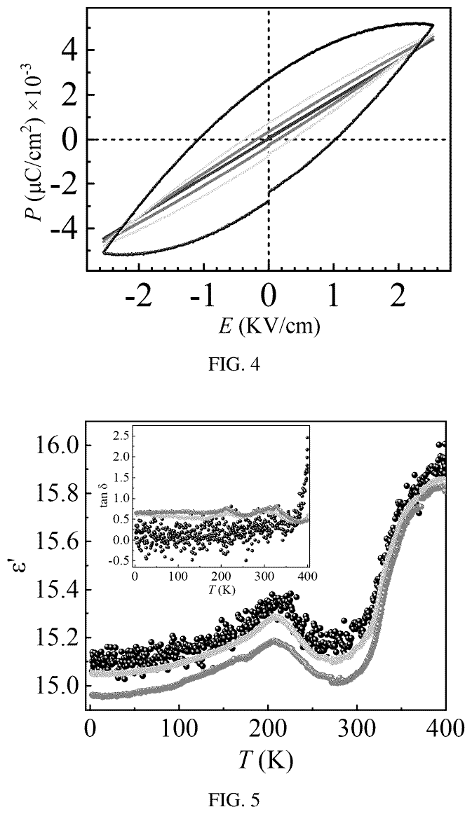

The hysteresis loop of the spinel-type single crystal in example 1 was tested at different temperatures, and the test results were shown in FIGS. 2-4.

As can be seen from FIGS. 2-4, the polarization intensity increases significantly with increasing temperature, and exhibits an excellent pyroelectricity, such that the single crystal also has certain research and potential applications in the field of infrared detection. In addition, the hysteresis loop shows a strong anisotropy and becomes “thin” at high temperatures.

Based on the above two experiments, it can be seen that the spinel-type single crystal provided in an example of the present disclosure has ferroelectricity and a relaxation property and belongs to a novel lead-free relaxor ferroelectric, which can be applied in energy storage materials or fast rechargeable products.

### Example 2

The dielectric constant ε and dielectric loss tan δ of the spinel-type single crystal in example 2 at different frequencies were tested as a function of temperature, with the change curve as shown in FIG. 5.

As can be seen from FIG. 5, the dielectric constant changes with temperature and shows an obvious ferroelectric transition peak at room temperature, indicating that the spinel-type single crystal provided in an example of the present disclosure has ferroelectricity and belongs to a novel lead-free ferroelectric, which can be applied in energy storage materials or fast rechargeable products.

### Example 3

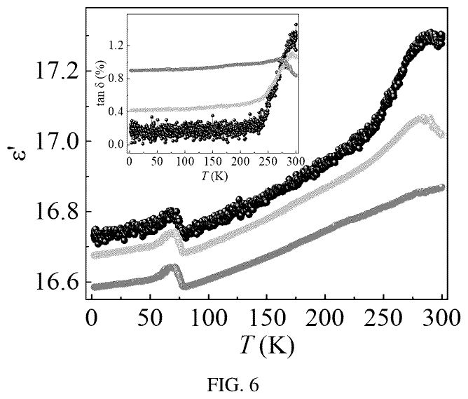

The dielectric constant E and dielectric loss tan δ of the spinel-type single crystal in example 3 at different frequencies were tested as a function of temperature, with the change curve as shown in FIG. 6.

As can be seen from FIG. 6, the dielectric constant changes with temperature and shows an obvious ferroelectric transition peak at room temperature, indicating that the spinel-type single crystal provided in an example of the present disclosure has ferroelectricity and belongs to a novel lead-free ferroelectric, which can be applied in energy storage materials or fast rechargeable products.

In summary, the spinel-type single crystals involved in the present disclosure exhibit ferroelectricity at room temperature, and some of the spinel-type single crystals also exhibit a relaxation property and can be used as relaxor ferroelectrics, which are lead-free and thus are non-toxic, harmless, green and environmentally friendly. The spinel-type single crystals mentioned above can be used as ferroelectrics, including relaxor ferroelectrics, in energy storage materials or rechargeable energy storage products.

The above is only preferred examples of the present disclosure and is not intended to limit the present disclosure. For a person skilled in the art, the present disclosure may have various changes and variations. Any modification, equivalent substitution, improvement, etc. made within the spirit and principle of the present disclosure shall fall within the scope of protection of the present disclosure.

### INDUSTRIAL APPLICABILITY

The present disclosure provides the use of spinel-type single crystals as ferroelectrics and relaxor ferroelectrics, an energy storage material, and a rechargeable energy storage product. The spinel-type single crystals AB₂O₄ involved in the present disclosure are lead-free and have ferroelectricity at room temperature, and some of the spinel-type single crystals also have a relaxation property and can be used as novel lead-free relaxor ferroelectrics, which are non-toxic, harmless, greener, and more environmentally friendly and therefore have significant practical performance.

1-13. (canceled)

14. A method of preparing a ferroelectric or relaxor ferroelectric, comprising the step of: providing a spinel-type single crystal AB₂O₄, wherein A is Ca, Sr, Ba, Ti, V, Cr, Mn, Fe, Co, Ni, Cu or Zn, and B is a transition metal element or a rare earth element.

15. The method of claim 14, wherein B is Sc, Y, La, Ce, Pr, Nd, Pm, Sm, Eu, Gd, Tb, Dy, Ho, Er, Tm, Yb or Lu.

16. The method of claim 14, wherein B is Al, Mn, Fe, Co, Ni, Sc, Y, La, Ce, Pr, Nd, Pm, Sm, Eu, Gd, Tb, Dy, Ho, Er, Tm, Yb or Lu.

17. The method of claim 14, wherein A is Sr, and B is Tb.

18. The method of claim 14, wherein the step of providing the spinel-type single crystal AB₂O₄ comprises the steps of: synthesizing a polycrystal powder of AB₂O₄ according to chemical composition of the spinel-type single crystal AB₂O₄; pressing the polycrystal powder of AB₂O₄ into a blank; and calcining the blank at 900-1400° C. for 12-48 hours, and then allowing the growth of the single crystal by using laser floating zone method.

19. The method of claim 14, wherein the single crystal is grown by using the laser floating zone method in an environment of inert gas atmosphere, with the content of oxygen in the inert gas atmosphere being less than or equal to 20%.

20. The method of claim 19, wherein the inert gas is argon.

21. The method of claim 14, wherein pressure intensity is controlled at 0-10 MPa when the laser floating zone method is used for growing the single crystal.

22. The method of claim 14, wherein the polycrystal powder of AB₂O₄ is pressed into a blank by means of isostatic pressing.

23. The method of claim 14, wherein the polycrystal powder of AB₂O₄ is pressed into a blank by means of charging the polycrystal powder of AB₂O₄ into a balloon and pressing and shaping same by means of isostatic pressing.

24. An energy storage material, comprising a spinel-type single crystal AB₂O₄, wherein A is Ca, Sr, Ba, Ti, V, Cr, Mn, Fe, Co, Ni, Cu or Zn, and B is a transition metal element or a rare earth element.

25. The material of claim 24, wherein B is Sc, Y, La, Ce, Pr, Nd, Pm, Sm, Eu, Gd, Tb, Dy, Ho, Er, Tm, Yb or Lu.

26. The material of claim 24, wherein B is Al, Mn, Fe, Co, Ni, Sc, Y, La, Ce, Pr, Nd, Pm, Sm, Eu, Gd, Tb, Dy, Ho, Er, Tm, Yb or Lu.

27. The material of claim 24, wherein A is Sr, and B is Tb.

28. A rechargeable energy storage product, comprising a spinel-type single crystal AB₂O₄, wherein A is Ca, Sr, Ba, Ti, V, Cr, Mn, Fe, Co, Ni, Cu or Zn, and B is a transition metal element or a rare earth element.

29. The product of claim 28, wherein B is Sc, Y, La, Ce, Pr, Nd, Pm, Sm, Eu, Gd, Tb, Dy, Ho, Er, Tm, Yb or Lu.

30. The product of claim 28, wherein B is Al, Mn, Fe, Co, Ni, Sc, Y, La, Ce, Pr, Nd, Pm, Sm, Eu, Gd, Tb, Dy, Ho, Er, Tm, Yb or Lu.

31. The product of claim 28, wherein A is Sr, and B is Tb.
